(19) United States
(12) Patent Application Publication
(10) Pub. No.: US 2006/0042674 A1
(43) Pub. Date: Mar. 2, 2006

(54) Thermoelectric converter

(76) Inventors: Takahiro Fujii, Ibaraki (JP); Takeo Honda, Ibaraki (JP)

Correspondence Address: MORGAN LEWIS & BOCKIUS LLP, 1111 PENNSYLVANIA AVENUE NW, WASHINGTON, DC, 20004, US

(21) Appl. No.: 10/532,221

(22) PCT Filed: Oct. 22, 2003
(86) PCT No.: PCT/JP03/13454

§ 371 Date: Apr. 22, 2005

(30) Foreign Application Priority Data
Oct. 23, 2002 (JP) 2002-307892

(51) Int. Cl. H01M 6/36; H01M 6/20; H01L 35/30

(52) U.S. Cl. 136/205; 429/11; 429/104; 429/112

(57) ABSTRACT

The present invention enables direct conversion of heat energy into electrical energy without generating any pressure difference between high- and low-temperature sides of electrolyte. In a container 107 creating a hermetic space, a solid electrolyte 101 comprising β″ alumina is brought into contact with sodium 102 connected to a cathode terminal 109 at the low-temperature side, and the solid electrolyte 101 is brought into contact with a porous electrode 103 connected to an anode terminal 108 at the high-temperature side. At the low-temperature side, the following reaction proceeds at the interface between the solid electrolyte 101 and sodium 102:
Na→Na⁺+e⁻
At the high-temperature side, the following reaction proceeds at the interface between the solid electrolyte 101 and the porous electrode 103:
Na⁺+e⁻→Na
Accordingly, power generation is conducted, and electrical power is supplied to a load 106.

### TECHNICAL FIELD

The present invention relates to a thermoelectric converter which directly converts heat energy into electrical energy.

### BACKGROUND ART

A power generation device which has been proposed by J. T. Kummer, et. al. and called a sodium heat engine or an alkali metal thermoelectric converter (AMTEC) is known as a thermoelectric converter which directly converts heat energy into electrical energy (for example, see Patent Document 1).

This power generation method has the following many advantages:
1. the output per electrode area of the generating device is large;
2. the output per unit weight is large;
3. the energy conversion efficiency is high;
4. the power generation scale can be freely selected;
5. it can be adapted to all heat sources; and
6. owing to the direct power generation, no operating portion is provided, neither vibration nor noise occurs, and reliability is high,
   and thus attracts much attention as a high power generation method with a great potential.

Some power generation devices utilizing this power generation principle have been reported. FIG. 10 shows a conventional power generation device. A solid electrolyte 201 such as β″ alumina is provided in a container 207, an anode side of the solid electrolyte 201 contacts with a porous electrode 203, and a cathode side thereof contacts with sodium 202 serving as an operating medium. A load 206 is connected between the anode side electrode and the cathode side electrode. An upper side portion of sodium 202 in FIG. 10 is heated by a high-temperature heat source 208, and the lower side portion is cooled by a low-temperature heat source (not shown in FIG. 10). At the lower side of FIG. 10, an electromagnetic pump 210 is provided, and sodium condensed with a condenser 209 is fed from the right side to the left side of FIG. 10 under pressure.

In this power generation device, sodium atoms supplied at the left side (cathode side) of the interface of the solid electrolyte 201 emit electrons and are ionized. The ionized sodium atoms move to the porous electrode 203 in the solid electrolyte 201, and accept electrons to be reduced at the porous electrode 203. Then, the sodium atoms absorb heat from the high-temperature heat source 208 and evaporate. Gas-phase sodium is returned to liquid-phase sodium with the condenser 209, and then supplied to the solid electrolyte 201 in a liquid phase by the electromagnetic pump 210. The electrons emitted at the cathode side of the solid electrolyte 201 pass through the load 206 to the porous electrode 203, and bind to sodium ions as described above.

Power generation is carried out in the cycle as described above, and direct-current power is supplied to the load 206.
Patent Document 1: Specification of U.S. Pat. No. 3,458,356

### DISCLOSURE OF THE INVENTION

It has been believed that the thermoelectric converter described above converts a vapor pressure difference of alkali metal (sodium) caused by a temperature difference to electromotive force by using a solid electrolyte, and thus it has been believed that an occurrence of the pressure difference between both sides of the solid electrolyte is a requirement. Therefore, it is necessary to air-tightly join the solid electrolyte to a container or a pipe made of a metal, ceramics or the like, and thus there is a problem that the processing is difficult and the production cost is high. Furthermore, it is also necessary to provide an electromagnetic pump for feeding an operating medium from a low-pressure side to a high-pressure side, or the like. Accordingly, it has such a drawback that complication and large-scale design of the device are unavoidable and the price of the device is increased. Furthermore, since the pressure difference is caused in the container, there is a problem with durability and also there is a problem that long-term reliability is lost. Still furthermore, when the solid electrolyte is broken, the operating medium randomly circulates, and a large quantity of heat is transferred to the low temperature side, so that there occurs a disadvantage that the heat source is overloaded.

The present invention aims to solve the problems of the above-described related art, and has an object to enable direct conversion of heat energy into electrical energy without using the pressure difference between areas sandwiching electrolyte.

In order to achieve the above-described object, the present invention provides a thermoelectric converter comprising:
an operating medium which is brought into contact with one end portion of an electrolyte medium having ion conductivity, wherein the operating medium is connected to a first terminal and emits an electron or binds to an electron by oxidation or reduction, and
a permeable electrode which is brought into contact with the other end portion of the electrolyte medium, wherein the permeable electrode is connected to a second terminal and allows the operating medium to permeate therethrough,
wherein the contact portion of the electrolyte medium with the operating medium is disposed at a low-temperature side while the contact portion of the electrolyte medium with the permeable electrode is disposed at a high-temperature side, and
the contact portion of the electrolyte medium with the operating medium and the contact portion of the electrolyte medium with the permeable electrode are set substantially under the same pressure.

In the present invention, “substantially under the same pressure” means that the pressure is not identical in a strict sense, but only a pressure difference is caused at such a degree that allows flow of vapor of the operating medium.

The inventors carried out experiments with a power generation device shown in FIG. 1(a) and found that substantially the same electromotive force as achieved when power is generated by using a pressure difference can be achieved without generating any pressure difference between anode and cathode sides of solid electrolyte. In FIG. 1(a), 1 represents a β″ alumina tube, 2 represents sodium serving as an operating medium, 3 represents a molybdenum electrode for conducting sodium reduction, 4 represents an α alumina tube, 5 represents a heater, 6 represents a potentio-galvanostat for conducting current-voltage measurement, and 7 represents a container. In this power generation device, the inside of the container was evacuated, and power generation was conducted under conditions that the molybdenum electrode 3 was kept at 712° C. and the sodium 2 was kept at 351° C. At this time, a current-voltage characteristic shown in FIG. 1(b) could be obtained.

Concequently, according to the present invention, heat energy can be directly converted into electrical energy without using the pressure difference. Therefore, according to the present invention, an effect of utilizing no pressure difference, that is, facilitation of a manufacturing and simplification and reduction in cost of the device can be achieved with keeping the advantage of the thermoelectric converter described above. Furthermore, durability of the device is increased, and no problem occurs even when solid electrolyte is broken.

### BRIEF DESCRIPTION OF THE DRAWINGS

FIG. 1 is a cross-sectional view showing a thermoelectric converter manufactured for testifing the operation of the device according to the present invention and a graph showing the experimental result.

FIG. 2 is a schematic cross-sectional view showing a first embodiment of the present invention.

FIG. 3 is a schematic cross-sectional view showing a second embodiment of the present invention.

FIG. 4 is a schematic cross-sectional view showing a third embodiment of the present invention.

FIG. 5 is a schematic cross-sectional view showing a fourth embodiment of the present invention.

FIG. 6 is a schematic cross-sectional view showing a fifth embodiment of the present invention.

FIG. 7 is a schematic cross-sectional view showing a sixth embodiment of the present invention.

FIG. 8 is a schematic cross-sectional view showing a seventh embodiment of the present invention.

FIG. 9 is a schematic cross-sectional view showing an eighth embodiment of the present invention.

FIG. 10 is a cross-sectional view showing a conventional thermoelectric converter.

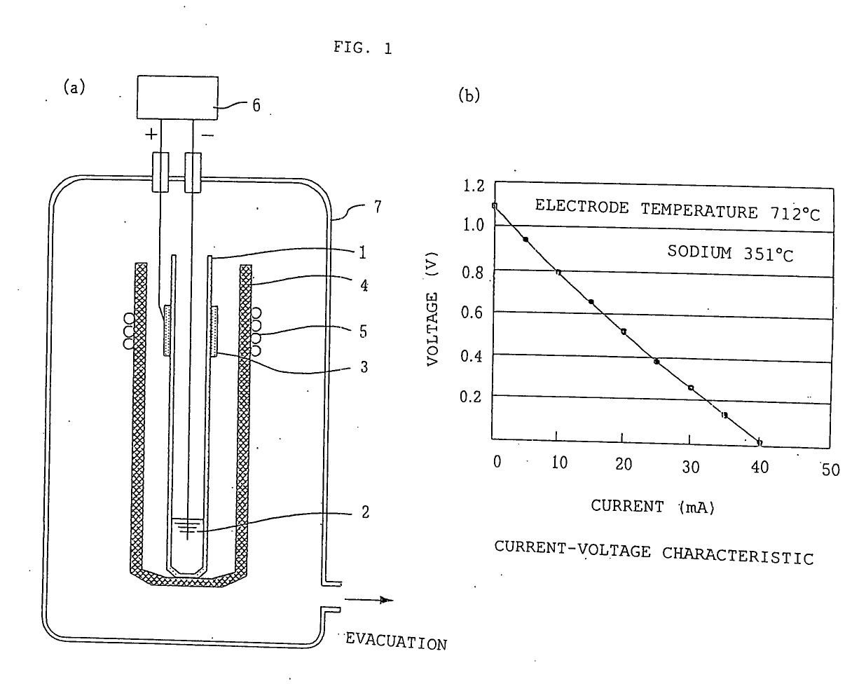

### BEST MODE FOR CARRYING OUT THE INVENTION

Next, embodiments according to the present invention will be described in detail with reference to the drawings.

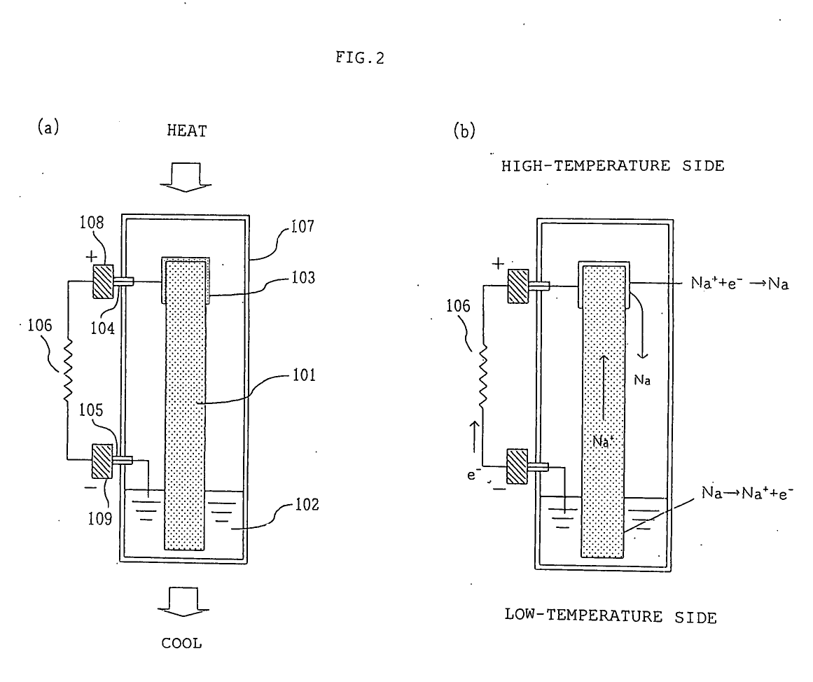

FIG. 2(a) is a cross-sectional view showing a first embodiment of the present invention. In FIG. 2(a), 101 represents a solid electrolyte comprising β″ alumina, 102 represents sodium serving as an operating medium, 103 represents a porous electrode which emits electrons to reduce sodium ions, each of 104 and 105 represents a bush comprising an insulating material, 106 represents a load, 107 represents a container creating a hermetic space, 108 represents an anode terminal, and 109 represents a cathode terminal. The inside of the container 107 is evacuated.

As shown in FIG. 2(a), in the thermoelectric converter, when the load is connected between the anode and cathode terminals and the porous electrode 103 side of the solid electrolyte 101 is heated while the sodium 102 side is cooled, electric power can be generated and supplied to the load. FIG. 2(b) is a cross-sectional view showing the power generation principle. In the thermoelectric converter, at the low-temperature side, the following reaction proceeds at the interface between the solid electrolyte 101 and the sodium 102.
Na→Na⁺+e⁻
Electrons are emitted through the sodium 102 to the anode terminal 109, and sodium ions are supplied to the solid electrolyte 101. At the high-temperature side of the solid electrolyte 101, electrons are supplied through the anode terminal 108 to the porous electrode 103, and the following reaction proceeds at the interface between the solid electrolyte 101 and the porous electrode 103, and sodium is generated.
Na⁺+e⁻→Na
Sodium thus generated is immediately vaporized and released into the vacuum container. The sodium vapor is condensed at the low-temperature side, and returned to liquid-phase sodium.

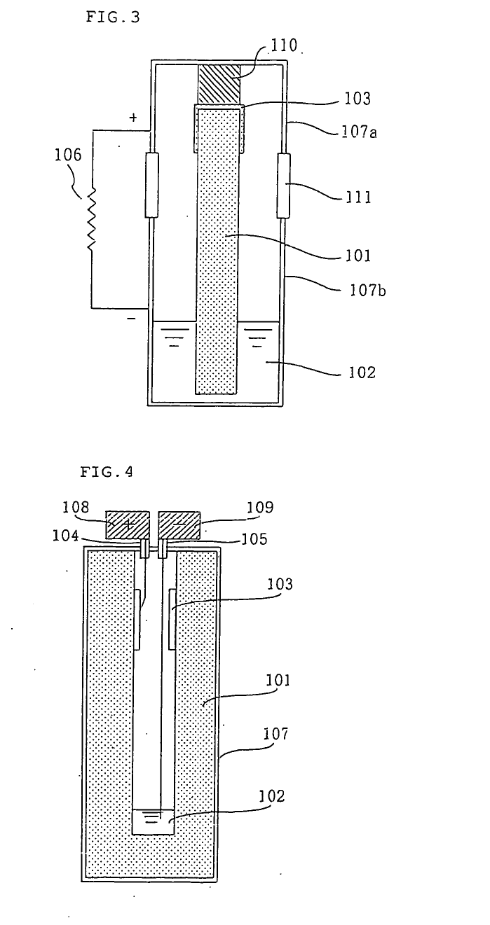

FIG. 3 is a cross-sectional view showing a second embodiment. In FIG. 3, the same portions as the first embodiment shown in FIG. 2(a) are represented by the same reference numerals and duplicated description thereof is omitted. The different point of this embodiment from the first embodiment shown in FIG. 2(a) resides in that a metal container is separated into an upper container 107a and a lower container 107b and the upper container 107a and the lower container 107b are electrically and thermally separated from each other by an insulating member 111, and that the porous electrode 103 and the upper container 102a are connected to each other by a connecting conductor 110 comprising a foamed metal or the like.

According to this embodiment, since the porous electrode 103 and the upper container 107a are connected to each other by the connecting conductor 110, the heat transfer efficiency from the outside to the inside is enhanced. Furthermore, since the high-temperature side and the low-temperature side are separated from each other by the insulating member 111, the thermal efficiency can be enhanced. In addition, the upper container 107a and the lower container 107b may be directly used as an anode terminal and a cathode terminal, respectively.

FIG. 4 is a cross-sectional view showing a third embodiment of the present invention. In FIG. 4, the same portions as the first embodiment shown in FIG. 2(a) are represented by the same reference numerals, and duplicated description thereof is omitted. In this embodiment, the solid electrolyte 101 is processed in a tubular shape having a bottom, and the container 107 is fixed to the external surface of the solid electrolyte 101 while a porous electrode is fixed onto the upper internal surface. The sodium 102 is enclosed in the solid electrolyte 101 in a tubular shape.

According to this embodiment, the cross-sectional area of the solid electrolyte 101 is increased to enhance the ion conductivity and reduce the inner resistance. Furthermore, the amount of sodium to be used can be reduced.

FIG. 5 is a cross-sectional view showing a fourth embodiment of the present invention. In FIG. 5, the same portions as the first embodiment shown in FIG. 2(a) are represented by the same reference numerals, and duplicated description thereof is omitted. In this embodiment, liquid-phase sodium is used by being impregnated in a sponge metal. That is, sodium condensed in the low-temperature portion is impregnated in the sponge metal, and a sodium-impregnated sponge metal 112 is connected to the cathode terminal 109. A wick-like metal may be used in place of the sponge metal.

According to this embodiment, the thermoelectric converter may be used in a free arrangement such as a horizontal arrangement, or an inverted arrangement. Furthermore, the thermoelectric converter may be adapted to a weightless state such as cosmic space.

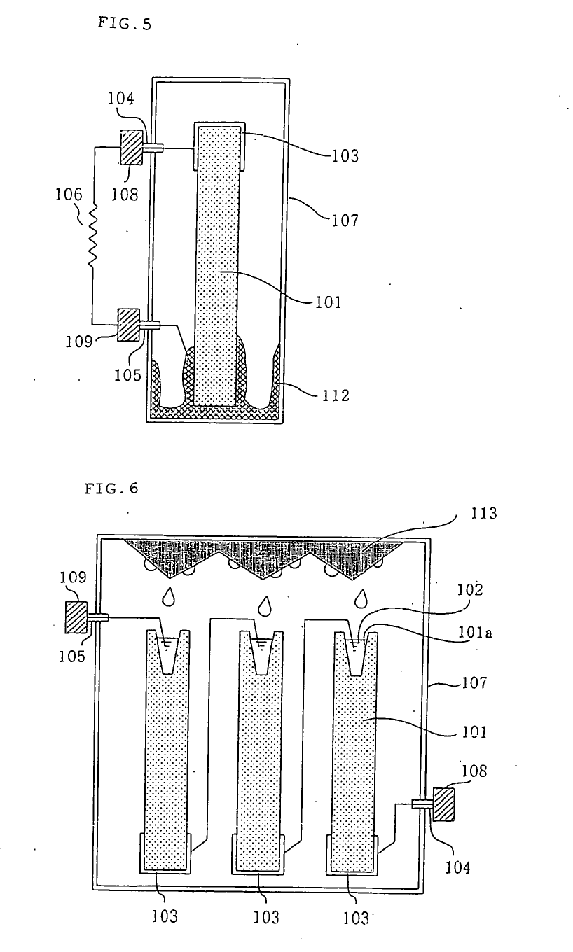

FIG. 6 is a cross-sectional view showing a fifth embodiment of the present invention. In FIG. 6, the same portions as the first embodiment shown in FIG. 2(a) are represented by the same reference numerals, and duplicated description thereof is omitted. In this embodiment, a cooling member 113 serving as a sodium condensing portion is disposed at the upper portion of the container 107, and the lower portion of the container is heated. The solid electrolyte 101 is set in an inverted arrangement with respect to the other embodiments, and a depressed portion 101a serving as a liquid reservoir is disposed at the upper portion of the solid electrolyte 101. The cooling member 113 is designed to have such a shape that condensed sodium is guided to the depressed portion 101a serving as the liquid reservoir. In this embodiment, plural cells are serially connected at plural stages. That is, the cathode terminal 109 is connected to the sodium 102 at the first-stage cell, and the porous electrode 103 of the first-stage cell is connected to the sodium 102 at the second-stage cell. The same connection as described above is successively carried out on the subsequent stages, and the porous electrode 103 of the final-stage cell (third-stage cell in the case of FIG. 6) is connected to the anode terminal 108.

According to this embodiment, the container 107, and the solid electrolyte and the porous electrode are insulated from each other, so that the plural cells may be serially connected and thus a high voltage can be achieved.

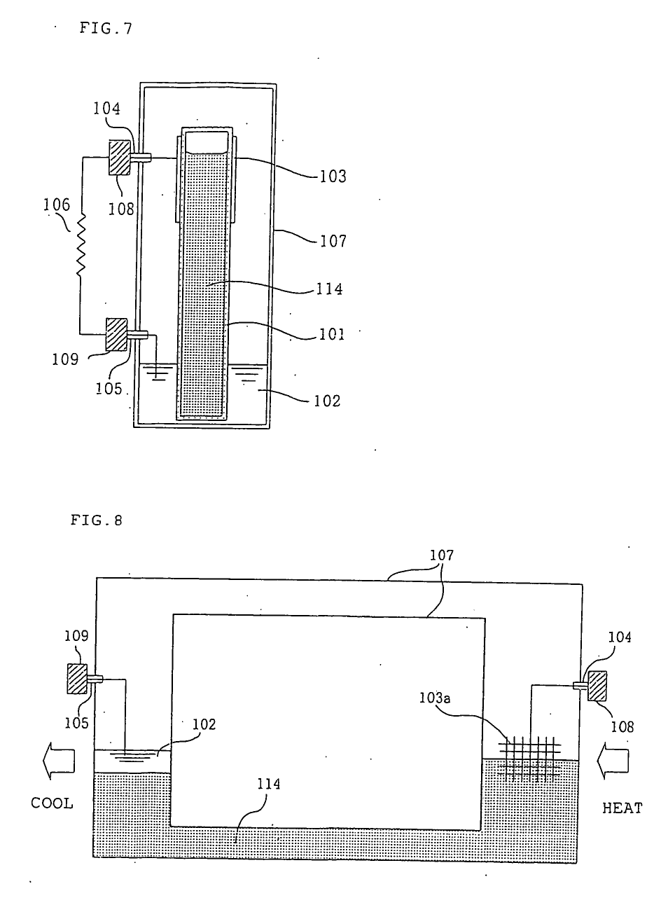

FIG. 7 is a cross-sectional view showing a sixth embodiment of the present invention. In FIG. 7, the same portions as the first embodiment shown in FIG. 2(a) are represented by the same reference numerals, and duplicated description thereof is omitted. In this embodiment, the solid electrolyte 101 is designed to be hollow, and a sodium-ion-conductive molten salt 114 is enclosed in the hollow portion. Since the enclosure of the molten salt 114 inside the solid electrolyte 101 is a compensation for low ion conductivity of the solid electrolyte 101, it is preferable that the molten salt 114 comprises a high-ion-conductive material. Furthermore, it is preferable that the molten salt 114 comprises a material which has a low melting point, and has a low vapor pressure even at a high temperature so that it is not decomposed and does not corrode the solid electrolyte 101. The space inside the solid electrolyte 101 is provided to meet a thermal expansion of the molten salt 114. However, the solid electrolyte 101 is not necessarily designed in a hermetic container, but it may be designed in an open type (that is, a tubular shape having a bottom).

In this embodiment, ionization of sodium occurs at the interface between the sodium 102 and the solid electrolyte 101, and sodium ions are emitted to the solid electrolyte 101 side. The sodium ions mainly pass through the molten salt having a large cross-section area and high ion conductivity and reach the anode side. Thereafter, the sodium ions pass through the solid electrolyte 101 side and are supplied to the porous electrode 103.

FIG. 8 is a cross-sectional view showing a seventh embodiment of the present invention. In FIG. 8, the same portions as the first embodiment shown in FIG. 2(a) are represented by the same reference numerals, and duplicated description thereof is omitted. In this embodiment, β″ alumina is not used, but only a molten salt 114 is used as the ion-conductive material. In place of a porous electrode, an electrode mesh 103a comprising a metal material is used. That is, in this embodiment, the molten salt 114 serving as the electrolyte material contacts with the electrode mesh 103a at an anode terminal 108 side at the high-temperature side, and contacts with liquid-phase sodium 102 at a cathode terminal 109 side at the low-temperature side. The characteristic of the molten salt 114 required in this embodiment is same as that of the sixth embodiment, that is, the sodium ion conductivity is high, the melting point is low, the vapor pressure even at high temperature is low so that the molten salt 114 is hardly decomposed.

According to the present invention, since it is not necessary to generate the pressure difference between the high- and low-temperature sides of the electrolyte, it is not required to use a solid material as the electrolyte. In the conventional thermoelectric converter, the solid electrolyte must be indispensably used and thus the material option is narrow. However, according to the present invention, materials may be selected from a broader range.

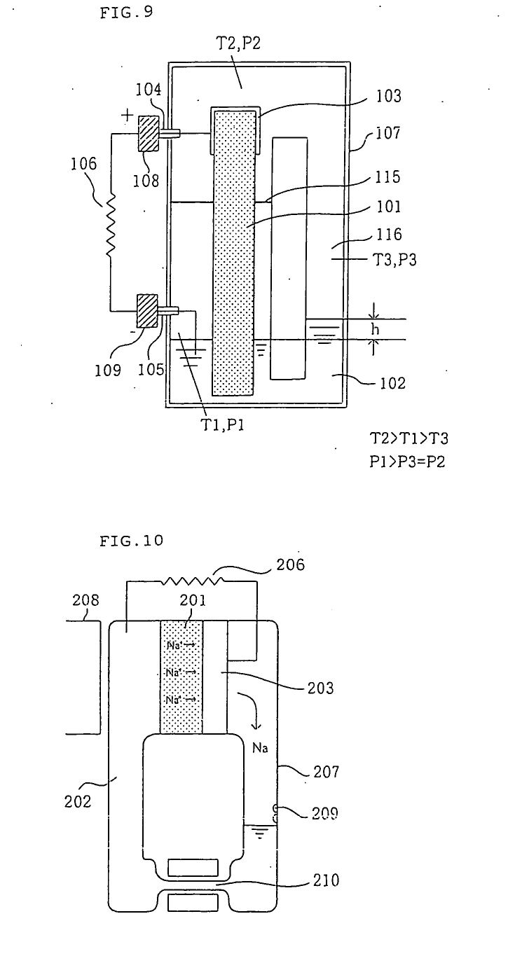

FIG. 9 is a cross-sectional view showing an eighth embodiment of the present invention. In FIG. 9, the same portions as the first embodiment shown in FIG. 2(a) are represented by the same reference numerals, and duplicated description thereof is omitted. In this embodiment, a condensing portion 116 is provided separately from a reaction portion of an operating medium in the container 107, and an anode side and a cathode side of the solid electrolyte 101 and a node space are separated from one another by a partition plate 115. In this power generation device, when the anode side of the solid electrolyte 101 is heated while the cathode side thereof is cooled (T2>T1), and also the temperature T3 of the condensing portion 116 is set to be lower than the temperature T1 of the cathode side of the solid electrolyte 101 (T1>T3), a difference between the vapor pressures P1 and P3 of sodium in the respective portions generates (P1>P3), so that the liquid surface at the condensing portion side of the sodium 102 is higher than that at the cathode side by h. That is, a slight pressure difference occurs between the anode and cathode sides of the solid electrolyte 101 due to the difference between the vapor pressures. Although the pressure difference is small, the ion conductivity of the solid electrolyte can be enhanced by setting T3 to a small value with keeping the vapor pressure P3 to a small value to keep the electromotive force, and setting T1 to a high value.

Although the preferred embodiments have been described above, the present invention is not limited to the above embodiments, and various modifications may be made without departing from the subject matter of the present invention. For example, the operating medium is not limited to an alkali metal represented by sodium, and materials other than described in the above embodiments can be used as the electrolyte material.

As described above, the thermoelectric converter according to the present invention directly converts heat energy to electrical energy without generating a pressure difference between both ends of the electrolyte material, and thus the following effects can be achieved with keeping the advantages of the conventional thermoelectric converter.

(1) It is not required to hermetically bond the solid electrolyte and the pipe or container, so that the manufacturing process can be simplified and facilitated and the production cost can be reduced.

(2) The converter is miniaturized and simplified, and thus a compact and low-price thermoelectric converter can be provided.

(3) Even when the solid electrolyte is broken, there occurs no problem which is more important than reduction in power generation efficiency or stop of power generation.

(4) Materials other than the solid electrolyte may be used as the electrolyte material, and a combination of materials which cannot be realized in the conventional thermoelectric converter can be performed.

1. A thermoelectric converter comprising:
an operating medium which is brought into contact with one end portion of an electrolyte medium having ion conductivity, wherein the operating medium is connected to a first terminal and emits an electron or binds to an electron by oxidation or reduction, and
a permeable electrode which is brought into contact with the other end portion of the electrolyte medium, wherein the permeable electrode is connected to a second terminal and allows the operating medium to permeate there through,
wherein the contact portion of the electrolyte medium with the operating medium is disposed at a low-temperature side while the contact portion of the electrolyte medium with the permeable electrode is disposed at a high-temperature side, and
the contact portion of the electrolyte medium with the operating medium and the contact portion of the electrolyte medium with the permeable electrode are set substantially under the same pressure.

2. The thermoelectric converter according to claim 1, wherein the electrolyte medium comprises a solid electrolyte material.

3. The thermoelectric converter according to claim 2, wherein the solid electrolyte material is β″ alumina.

4. The thermoelectric converter according to claim 1, wherein the electrolyte medium comprises electrolyte materials having different ion conductivity.

5. The thermoelectric converter according to claim 1, wherein the electrolyte medium comprises a hollow member which comprises a solid electrolyte material and is designed in a hollow shape or a tubular shape having a bottom, and a liquid electrolyte material introduced in the hollow member.

6. The thermoelectric converter according to claim 5, wherein the solid electrolyte material is β″ alumina.

7. The thermoelectric converter according to claim 5, wherein the liquid electrolyte material is a molten salt.

8. The thermoelectric converter according to claim 1, wherein the electrolyte medium comprises a liquid electrolyte material.

9. The thermoelectric converter according to claim 8, wherein the liquid electrolyte material is a molten salt.

10. The thermoelectric converter according to claim 1, wherein the operating medium is an alkali metal.

11. The thermoelectric converter according to claim 10, wherein the alkali metal is sodium.

12. The thermoelectric converter according to claim 1, wherein the operating medium is impregnated in an impregnation member.

13. A thermoelectric converter comprising:
an operating medium which is brought into contact with one end portion of an electrolyte medium having ion conductivity, wherein the operating medium is connected to a first terminal and emits an electron or binds to an electron by oxidation or reduction, and
a permeable electrode which is brought into contact with the other end portion of the electrolyte medium, wherein the permeable electrode is connected to a second terminal and allows the operating medium to permeate therethrough,
wherein the operating medium is vaporized at the permeable electrode while the operating medium is condensed at a condensing portion,
the contact portion of the electrolyte medium with the operating medium is disposed at a low-temperature side while the contact portion of the electrolyte medium with the permeable electrode is disposed at a high-temperature side, and
a pressure difference between the contact portion of the operating medium with the first terminal and the condensing portion is equal to or less than a vapor pressure difference of the operating medium which is caused by a temperature difference between the contact portion of the operating medium with the first terminal and the condensing portion.

14. The thermoelectric converter according to claim 13, wherein a partition plate for separating both spaces of the contact portion of the electrolyte medium with the operating medium and the contact portion of the electrolyte medium with the permeable electrode is disposed between the contact portion of the electrolyte medium with the operating medium and the contact portion of the electrolyte medium with the permeable electrode.

15. The thermoelectric converter according to claim 13, wherein the contact portion of the electrolyte medium with the operating medium has a higher temperature than the condensing portion.

16. The thermoelectric converter according to claim 13, wherein the electrolyte medium comprises a solid electrolyte material.

17. The thermoelectric converter according to claim 13, wherein the operating medium is an alkali metal.

18. The thermoelectric converter according to claim 17, wherein the alkali metal is sodium.

19. The thermoelectric converter according to claim 13, wherein the operating medium is impregnated in an impregnation material.

20. The thermoelectric converter according to claim 13, wherein the electrolyte medium comprises electrolyte materials having different ion conductivity.

21. The thermoelectric converter according to claim 13, wherein the electrolyte medium comprises a hollow member which comprises a solid electrolyte material and is designed in a hollow shape or a tubular shape having a bottom, and a liquid electrolyte material introduced in the hollow member.

22. The thermoelectric converter according to claim 21, wherein the solid electrolyte material is β″ alumina.
